(19) United States
(12) Patent Application Publication
(10) Pub. No.: US 2024/0186064 A1
(43) Pub. Date: Jun. 6, 2024

(54) SOFT MAGNETIC MULTILAYER DESPOSITION APPARATUS, METHODS OF MANUFACTURING AND MAGNETIC MULTILAYER

(71) Applicant: Evatec AG, Trubbach (CH)

(72) Inventors: Claudiu Valentin Falub, Zurich (CH); Martin Bless, Malans SG (CH)

(21) Appl. No.: 18/440,448

(22) Filed: Feb. 13, 2024

Related U.S. Application Data
(62) Division of application No. 16/607,829, filed on Oct. 24, 2019.

(30) Foreign Application Priority Data
Apr. 27, 2017 (CH) 00562/17

(51) Int. Cl. H01F 41/18; B32B 15/04; C22C 19/07; C22C 38/00; C22C 38/10; C23C 14/06; C23C 14/14; C23C 14/34; C23C 14/35; C23C 14/50; C23C 14/56; H01F 1/147; H01J 37/34

(52) U.S. Cl. CPC H01F 41/183; B32B 15/04; C22C 19/07; C22C 38/002; C22C 38/10; C23C 14/067; C23C 14/14; C23C 14/345; C23C 14/3464; C23C 14/352; C23C 14/505; C23C 14/568; H01F 1/147; H01F 41/18; H01J 37/3417; H01J 37/3429; H01J 37/3447; C22C 2202/02

(57) ABSTRACT

The soft magnetic material multilayer deposition apparatus includes a circular arrangement of a multitude of substrate carriers in a circular inner space of a vacuum transport chamber. In operation the substrate carriers pass treatment stations. One of the treatment stations has a sputtering target made of a first soft magnetic material. A second treatment station includes a target made of a second soft magnetic material which is different from the first soft magnetic material of the first addressed target. A control unit controlling relative movement of the substrate carriers with respect to the treatment stations provides for more than one 360° revolution of the multitude of substrate carriers around the axis AX of the circular inner space of the vacuum transport chamber, while the first and second treatment stations are continuously operative.

This application is a divisional application of U.S. application Ser. No. 16/607,829, filed Oct. 24, 2019, which is the U.S. National Stage of PCT International Application No. PCT/EP2018/059943, filed on Apr. 18, 2018, which claims the benefit of Switzerland Patent Application No. 00562/17, filed Apr. 27, 2017. These applications are hereby incorporated herein by reference in their entireties.

There exists the need for miniaturization of integrated induction-based devices as e.g. of transformers, induction coils etc. operating at very high frequencies up to several GHz.

E.g. from U.S. Pat. No. 7,224,254 it is known to realize such devices by depositing multiple layers of different soft magnetic materials on substrates.

The present invention departs from the recognition, that by stacking very thin layers of at least two soft magnetic materials, an overall behavior of the layer stack results with improved characteristics for high frequency magnetic applications thereby allowing further reducing the size of inductive micro devices on substrates and improved high-frequency behavior.

For industrial applications, techniques should be available to deposit efficiently and well-controlled stacks of very thin layers of soft magnetic materials.

This is realized by the soft magnetic material multilayer deposition apparatus according to the present invention. It comprises a circular inner space vacuum transport chamber about an axis. Thereby the term “circular” is to be understood as including a polygon approximation of the respective circles. As will be addresses later, the circular inner space may be annular shaped or cylindrical. The axial extent if the circular inner space relative to its radial extent may be large or small.

Along a plane perpendicular to the axis, a circular arrangement of a multitude of substrate carriers is provided, in the inner space and coaxially to the axis.

Along a plane perpendicular to the axis, there is provided a circular arrangement of substrate treatment stations, the stations thereof treatment-operative into the inner space.

There is further provided a rotational drive operationally coupled between the circular arrangement of the multitude of substrate carriers and the circular arrangement of treatment stations, so as to establish a relative rotation between the circular arrangement of the multitude of substrate carriers and the circular arrangement of treatment stations.

The circular arrangement of the multitude of substrate carriers and the circular arrangement of treatment stations are mutually aligned. Either they are aligned as being provided along a common plane perpendicular to the axis, or they are aligned in that the two circular arrangements are arranged along equal radius circles with respect to the axis.

Each substrate carrier is constructed to accommodate a substrate so that one of the extended surfaces—that surface to be treated by the apparatus—of each of the substrates subsequently faces the stations of the arrangement of treatment stations as the relative rotation of the two circular arrangements is established by the rotational drive.

Depending on the specific technique of depositing the layer stack and of its overall structure, the arrangement of treatment stations may comprise different layer deposition stations e.g. for reactive or non-reactive sputter deposition of electrically conductive or of dielectric materials, etching stations etc.

Specifically, and according to the invention, the arrangement of substrate treatment stations comprises at least one first and at least one second sputter deposition station, each with a single target.

The first sputter deposition station has a first target of a first soft magnetic material. Thus, the first soft magnetic material to be deposited as a very thin layer on the substrates is sputtered from solid single target and not reactively. If the first target is of a mixed material, e.g. of two or more than two ferromagnetic elements and/or comprises one or more than one non-ferromagnetic element, sputter deposition from the solid of a single target allows a highly accurate control of the stoichiometry of the deposited first material and of accurate stability of its stoichiometry over time. Dependent on the characteristics of this first soft magnetic material with respect to sputtering, DC-, pulsed DC- including HIPIMS- or Rf-single or multiple frequency supplied sputtering is applied.

The second sputter deposition station has a target of a second soft magnetic material, different from the first soft magnetic material. Please note, that under a most generic aspect, “different” may also mean the same material composition but with different stoichiometry.

The second soft magnetic material to be deposited as a very thin layer on the substrates is as well sputtered from single target solid and not reactively. If the second target is of a mixed material, e.g. of two or more than two ferromagnetic elements and/or comprises one or more than one non-ferromagnetic elements, sputter deposition from the single target solid allows a highly accurate control of the stoichiometry of the deposited second material and of accurate stability of its stoichiometry over time. Dependent on the characteristics of this second soft magnetic material with respect to sputtering, DC-, pulsed DC- including HIPIMS- or Rf-single or multiple frequency supplied sputtering is applied.

The apparatus further comprises a control unit operationally coupled to the stations of the arrangement of treating stations and to the rotational drive. The control unit controls the first and the second sputter deposition stations so as to be continuously sputter deposition enabled towards said substrate carriers, at least during more than one 360° relative revolutions of the circular arrangement of the multitude of substrate carriers relative to the circular arrangement of treatment stations, about the addressed axis, the addressed revolutions directly succeeding one another.

Thus, sputter operation of at least the first and the second sputter deposition stations and respective sputtering towards the arrangement of the multitude of substrate carriers is not interrupted during the more than one relative revolutions of the arrangement of the multitude of substrate carriers with respect to the arrangement of treatment stations. Thereby any transitional states of sputtering effect are avoided as may occur by intermittently enabling and disabling sputter deposition.

In one embodiment of the apparatus according to the invention, the circular inner space is annular and the arrangement of said multitude of substrate carriers or the arrangement of treatment stations is mounted to the radially outer circular surface of the annular or to the top surface or to the bottom surface of the annular inner space.

In one embodiment of the apparatus according to the invention, the circular inner space is annular and the arrangement of said multitude of substrate carriers or said arrangement of treatment stations is mounted to the radially inner circular surface of said annular inner space.

In one embodiment of the apparatus according to the invention, the circular inner space is cylindrical and the arrangement of the multitude of substrate carriers or the arrangement of treatment stations is mounted to the circular surface, which is the surrounding surface of the cylindrical inner space, or to the bottom surface or to the top surface of the cylindrical inner space.

In one embodiment of the apparatus according to the invention, the arrangement of treatment stations is stationary and the arrangement of the multitude of substrate carriers is rotatable. It is nevertheless also possible to keep the arrangement of the multitude of substrate carriers stationary and to rotate the arrangement of treatment stations.

In one embodiment of the apparatus according to the invention, the first target comprises or consists of one or more than one of the elements of the group Fe, Ni, Co and the second target comprises or consists of one or more than one element out of the group Fe, Ni, Co.

Please note that the two target materials according to the invention are different:

Thus, if the two targets consist each of one single of the addressed elements, then the targets are of different elements out of the addressed group.

If the targets consist each of two of the addressed elements, they consist of different couples out of the addressed group or they consist of the same couples out of the addressed group but at different stoichiometry.

If the targets consist each of all three elements of the addressed group, then they are different with respect to stoichiometry.

In one embodiment of the apparatus according to the invention, the first target consists of one or more than one element out of the group Fe, Ni, Co and of at least one non-ferromagnetic element and/or the second target consists of one or more than one element out of the group Fe, Ni, Co and of at least one non-ferromagnetic element.

Thus, the difference of the materials of the first and second targets may be based on difference of the one or more than one ferromagnetic elements as addressed above and/or on the difference with respect to the one or more than one non-ferromagnetic elements, including differences just based on different stoichiometry.

In one embodiment of the apparatus according to the invention, the at least one non-ferromagnetic element just addressed is at least one element out of the groups IIIA, IVB and VB of the periodic system (according to groups 13,4,5 of IUAPC).

In one embodiment of the apparatus according to the invention, the at least one non-ferromagnetic element just addressed is at least one element out of the group B, Ta, Zr.

In one embodiment of the apparatus according to the invention, the first target comprises or consists of one or more than one element of the group Fe, Ni, Co and the second target comprises or consists of one or more than one element of the group Fe, Ni, Co and further comprising at least one further sputter deposition station neighboring the first and/or the second sputter deposition station and having a target of at least one non ferromagnetic element.

In one embodiment of the just addressed embodiment, the at least one non-ferromagnetic element of the target of the further sputter deposition station is at least one element out of the groups IIIA, IVB and VB of the periodic system (according to groups 13,4,5 of IUAPC).

In one embodiment of the just addressed embodiment the at least one non-ferromagnetic element is at least one out of the group B, Ta, Zr.

During the more than one 360° relative revolutions of the arrangement of the multitude of substrate carriers with respect to the arrangement of treatment stations and about the addressed axis, the substrates are coated more than one time with very thin layers at least of the first and of the second soft magnetic materials. If the arrangement of substrate treatment stations does not comprise an additional treatment station between the first and second sputter deposition stations—also called sputtering stations-or the substrate treatment by such an additional treatment station is disabled during the addressed revolutions, very thin layers of the first and of the second soft magnetic materials are deposited directly one upon the other.

If further the arrangement of treatment stations does not comprise further treatment stations, treatment-enabled during the addressed revolutions, a stack of first and second soft magnetic material layers is realized on the substrates. The number of very thin layers of the stack is governed by the number of 360° relative revolutions. Clearly more than one first sputter deposition station and more than one second sputter deposition station may be provided in the arrangement of treatment stations, so that more than two first and second soft magnetic material layers are deposited on the substrates per 360°-revolution directly one upon the other or separate by at least one very thin layer, deposited by at least one further layer depositing station of the arrangement of treatment stations and deposition-enabled as well during the more than one 360° relative revolutions.

Per the addressed more than one 360° revolutions, directly subsequent to depositing a respective very thin layer of one of the first and/or of the second ferromagnetic target materials as was addressed, a very thin layer of a non-ferromagnetic material may be deposited by a further sputter deposition station which is deposition-enabled like the first and second sputter deposition stations.

In one embodiment of the apparatus according to the invention, the control unit controls the rotational drive and thus relative rotation of the arrangement of the multitude of substrate carriers with respect to the arrangement of treatment stations, in a stepped manner.

In one embodiment of the apparatus according to the invention, the control unit controls the rotational drive, and thus the relative rotation of the arrangement of the multitude of substrate carriers with respect to the arrangement of treatment stations, for continuous relative rotation at a constant angular velocity with respect to said axis, for at least some of said more than one 360° revolutions directly succeeding one another.

Thus, one of these relative revolutions may be performed at a first constant angular velocity, another at a different constant velocity. Combined with controlling the first and the second sputter deposition stations to continuously sputter at least during the more than one directly succeeding 360° relative revolutions of the arrangement of the multitude of substrate carriers about the addressed axis, transitional, hard to control deposition behaviors are avoided.

In one embodiment of the apparatus according to the invention, the control unit controls sputtering power of at least the first and of at least the second sputter deposition stations in dependency of an exposure time each of said substrate carriers is exposed to said first and to said second sputter deposition stations respectively, so as to sputter deposit by each of said first and second sputter deposition stations a layer of said first and of said second materials, respectively, of a respectively desired thickness d₁,d₂.

In one embodiment of the embodiment just addressed the control unit performs control so that there is valid:
10 nm≥(d₁,d₂)≥0.1 nm.

In one embodiment the control unit performs control so that there is valid:
5 nm≥(d₁,d₂,)≥0.1 nm.

In one embodiment the control unit performs control so that there is valid:
1 nm≥(d₁,d₂,)≥0.1 nm.

In one embodiment the control unit performs control so that there is valid:
0.5 nm≥(d₁,d₂,)≥0.1 nm or
0.5 nm≥(d₁,d₂,)≥0.2 nm.

In one embodiment the control unit performs control so that the thicknesses d₁ and d₂ are equal.

In one embodiment the control unit performs control so that d₁ and d₂ are 1 nm.

In one embodiment the control unit performs control so that at last one of d₁ and d₂ is <1 nm.

In one embodiment the control unit performs control so that there is valid at least one of:
0.1 nm≤(d₁,d₂)≤3 nm
0.3 nm≤(d₁,d₂)≤2 nm
0.5 nm≤(d₁,d₂)≤1.5 nm.

In one embodiment the control unit performs control so that the first and second layers reside directly one upon the other.

In one embodiment the first sputtering station is constructed to deposit FeCoB and the second sputtering station is constructed to deposit CoTaZr.

In one embodiment the control unit performs control so that the substrate carriers repeatedly pass the first and the second sputtering stations a multitude of times.

In one embodiment of the apparatus according to the invention, the arrangement of treatment stations comprises at least one further layer deposition station. The control unit, on one hand, controls the further layer deposition station so as to continuously deposit at least during the more than one 360° revolutions. The control unit further controls the material deposition rate of the further layer deposition station, in dependency of an exposure time each of the substrate carriers is exposed to the further layer deposition station, so that, by the further layer deposition station, a layer of a desired thickness d₃ is deposited. Thereby and in a good embodiment the addressed further layer deposition station is a sputter deposition station for a non-ferromagnetic material or element as was addressed above.

In one embodiment of the apparatus according to the invention, there the control unit performs control so that for the desired thicknesses, d₃, there is valid:
10 nm≥(d₃)≥0.1 nm.

Thereby in one embodiment the control unit performs control so that there is valid
5 nm≥d₃≥2 nm.

In one embodiment of the apparatus according to the invention, the apparatus comprises more than one of the first sputter deposition stations.

In one embodiment of the apparatus according to the invention, the apparatus comprises more than one of the second sputter deposition stations.

In one embodiment of the apparatus according to the invention, the first and the second sputter deposition stations are a pair of neighboring stations along the inner space of the vacuum transport chamber.

In one embodiment of the apparatus according to the invention, comprising a multitude of the just addressed pairs, the first and second sputter deposition stations are arranged alternatingly.

In one embodiment of the apparatus according to the invention, the first and the second sputter deposition stations are two stations of a group of more than two-layer deposition stations, the layer deposition stations of the group are provided along the inner space one neighboring the other, and the stations of the group are simultaneously deposition-activated by control of the control unit.

Thus, there may be provided e.g. one further layer deposition station just ahead the first sputter deposition station and/or between the first and second sputter deposition station and/or just following the second sputter deposition station, considered in one direction of relative rotation of the arrangement of the multitude of substrate carriers with respect to the arrangement of treatment stations. All station members of the group are simultaneously deposition-activated as controlled by the controller unit.

In one embodiment of the apparatus according to the invention, the apparatus comprises more than one of the groups and/or comprises different of the groups.

Thus, e.g. multiple three-station groups may be provided and/or groups with different numbers of stations and/or with different stations.

In one embodiment of the apparatus according to the invention, the arrangement of substrate treatment stations comprises at least one further sputter deposition station constructed to sputter deposit a further material on or towards the substrates or substrate holders.

In one embodiment of the apparatus according to the invention, the addressed material is a non-magnetic metal or a non-magnetic metal alloy or a dielectric material.

The dielectric material may e.g. be aluminum oxide, silicon oxide, tantalum oxide, silicon nitride, aluminum nitride or the respective carbides, oxi-carbides, nitro-carbides etc.

In one embodiment of the apparatus according to the invention, the control unit controllably enables and disables treatment of the substrates by selected ones or by all of said treatment stations. Selected disabling of treatment stations of the arrangement of substrate treatment stations including the first and the second sputter deposition stations may be applied e.g. for loading substrates to and/or unloading substrates from the apparatus, thereby maintaining overall treatment of all substrates equal.

Disabling and enabling substrate treatment by the respective stations may be performed by shutters, closing or opening the treatment connection from the stations to the substrate carriers and/or by switching on and off the electrical supply to the respective stations. Making use of shutters avoids switching transitional behaviors.

In one embodiment of the apparatus according to the invention the control unit controls the rotational drive for continuous relative rotation at a constant angular velocity with respect to the axis for at least one of said more than one 360° relative revolutions directly succeeding one another and to inverse direction of revolution of the rotational drive. By inverting relative rotational or revolution direction of the arrangement of the multitude of substrate carriers with respect to the arrangement of treatment stations, layer deposition may be homogenized.

In one embodiment of the apparatus according to the invention, at least one of the first and of the second sputter deposition stations comprises a collimator downstream the respective target. By such collimator a desired microstructure may be induced in the very thin layer which leads to desired magnetic properties.

In one embodiment of the apparatus according to the invention, one of the first and of the second targets is of Feₓ₁Co_{y1}, the arrangement of treatment stations comprising a further sputtering station neighboring suceedingly succeeding the one sputtering station and having a target of Boron. The further sputtering station is controlled by the control unit to be deposition-enabled during the same time as the one sputtering station, and wherein there is valid x1+y1=100 and 20<y1<50.

In one embodiment of the apparatus according to the invention, one of the first and of the second targets is of Co. The arrangement of treatment stations comprises at least two further sputtering stations, neighboring succeedingly the one sputtering station and having targets of Ta and of Zr respectively. The further sputtering stations are controlled by the control unit to be deposition-enabled during the same time as the one sputtering station.

In one embodiment of the apparatus according to the invention, at least one of the first and of the second targets is of Feₓ₂Co_{y2}B_{z2}, wherein x2+y2+z2=100.

In one embodiment of the just addressed embodiment the arrangement of treatment stations comprises at least one further layer deposition station constructed to deposit a dielectric material layer.

In one embodiment of the apparatus according to the invention, at least one of the first and of the second targets is of Niₓ₃Fe_{y3}, wherein x3+y3=100 and there is valid 50<y3<60 or 17.5<y3<22.5.

In one embodiment of the apparatus according to the invention, the first target is of Feₓ₄Co_{y4}, the second target of Niₓ₅Fe_{y5} and there is valid x4+y4=100 and x5+y5=100 and 5<y4<20 and 17.5<y5<22.5 or 50<y5<60.

In one embodiment of the apparatus according to the invention, the first target consists of Feₓ₆Co_{y6}B_{z6} and the second target consists of Coₓ₇Ta_{y7}Zr_{z7}, wherein x6+y6+z6=100 and x7+y7+z7=100.

In one embodiment of just addressed embodiment there is valid:
x6>y6.

In one embodiment of the apparatus according to the invention as just addressed there is valid:
y6≥z6.

In one embodiment of the apparatus according to the invention as just addressed there is valid:
x7>y7.

In one embodiment of the apparatus according to the invention as just addressed there is valid:
y7≥z7.

In one embodiment of the apparatus according to the invention as just addressed there is valid at least one or more than one of:
45≤x6≤60,
50≤x6≤55,
x6=52,
20≤y6≤40,
25≤y6≤30,
y6=28,
10≤z6≤30,
15≤z6≤25,
z6=20.

In one embodiment of the apparatus according to the invention as just addressed there is valid at least one or more than one of:
85≤x7≤95,
90≤x7≤93,
x7=91.5,
3≤y7≤6,
4≤y7≤5,
y7=4.5,
2≤z7≤6,
3≤z7≤5,
z7=4.

In one embodiment of the apparatus according to the invention, the control unit controls the relative rotation and/or the power applied to at least the first and the second targets and possibly to further layer deposition stations of the arrangement of treatment stations so as to deposit by each of said first and second sputter deposition stations and possibly at least one further layer deposition station, per substrate exposure thereto, a layer of a respective thickness d for which there is valid at least one of:
0.1 nm≤d≤3 nm
0.3 nm≤d≤2 nm
0.5 nm≤d≤1.5 nm.

Two or more than two embodiments of the apparatus according to the invention and as addressed may be combined unless being in contradiction.

The invention is further directed to a method of manufacturing a substrate with an induction device comprising a core, the core comprising thin layers deposited by sputtering, wherein at least a part of the thin layers is deposited by means of an apparatus according to the invention or by one or more than one of the addressed embodiments of this apparatus.

The invention is further directed to a method of manufacturing a substrate with a core for an induction device, the core comprising thin layers deposited by sputtering, wherein at least a part of the thin layers is deposited by means of an apparatus according to the invention or by one or more than one of the addressed embodiments of this apparatus.

The invention is further directed to a soft magnetic multilayer stack comprising first layers of a first soft-magnetic material, second layers of a second soft-magnetic material, the second soft-magnetic material being different from the first soft-magnetic material, the first layers having each a thickness d₁, the second layers having each a thickness d₂ and wherein there is valid
5 nm≥(d₁,d₂)≥0.1 nm.

Thereby the thicknesses d₁ and d₂ may vary from individual layer to individual layer within the addressed ranges for d₁ and d₂.

In one embodiment of the soft magnetic multilayer stack according to the invention there bis valid:
1 nm≥(d₁,d₂)≥0.1 nm.

In one embodiment of the soft magnetic multilayer stack according to the invention there is valid at least one of:
0.1 nm≤(d₁,d₂)≤3 nm,
0.3 nm≤(d₁,d₂)≤2 nm,
0.5 nm≤(d₁,d₂)≤1.5 nm.

In one embodiment of the soft magnetic multilayer stack according to the invention there is valid:
0.5 nm≥(d₁,d₂,)≥0.1 nm
or
0.5 nm≥(d₁,d₂,)≥0.2 nm.

In one embodiment of the soft magnetic multilayer stack according to the invention the thicknesses d₁ and d₂ are equal.

In one embodiment of the soft magnetic multilayer stack according to the invention d₁ and d₂ are 1 nm.

In one embodiment of the soft magnetic multilayer stack according to the invention at last one of d₁ and of d₂ is smaller than 1 nm.

In one embodiment of the soft magnetic multilayer stack according to the invention the first and the second layers reside directly one upon the other.

In one embodiment of the soft magnetic multilayer stack according to the invention the first layers are of FeCoB and the second layers are of CoTaZr.

In one embodiment of the soft magnetic multilayer stack according to the invention the first and second layers reside directly one upon the other, the stack comprising a multitude of the first and of the second layers, the multitude being covered by a layer of non-ferromagnetic material.

In one embodiment the addressed non-ferromagnetic material is AlO₂.

One embodiment the soft magnetic multilayer comprises more than one of the addressed multitude, with at least one respective layer of the non-ferromagnetic material therebetween.

The invention is further directed on a soft-magnetic multilayer comprising:
A multitude of FeCoB layers,
A multitude of CoTaZr layers,
the layers of FeCoB residing in an alternating manner directly on the layers of CoTaZr, the common multitude of FeCoB layers and of CoTaZr layers being covered by a layer of AlO₂.

In one embodiment of the soft magnetic multilayer stack according to the invention as just addressed, the layers of FeCoB have a thickness d₁ and the layers of CoTaZr have a thickness d₂,d₁ and d₂ being equal.

In one embodiment of the soft magnetic multilayer stack according to the invention as just addressed there is valid at least one of: 0.1 nm≤(d₁,d₂)≤3 nm,
0.3 nm≤(d₁,d₂)≤2 nm,
0.5 nm≤(d₁,d₂)≤1.5 nm.

In one embodiment of the soft magnetic multilayer stack according to the invention as just addressed d₁ and d₂ are smaller than 1 nm, down to 0.2 nm.

The invention is further directed on a core for an induction device or an inductive device with a core, wherein the core comprises at least one soft magnetic multilayer according to the invention or according to one or more than one embodiments thereof.

Please note that one or more than one of the embodiments of the magnetic multilayers according to the invention may be combined with one or more than one of the respective embodiments, if not contractionary.

### BRIEF DESCRIPTION OF THE DRAWINGS

In spite of the fact the invention becomes clear to the skilled artisan already from the above description, the invention shall now be additionally exemplified with the help of figures. The figures show:

FIG. 1: Schematically and simplified an embodiment of the apparatus according to the invention;

FIG. 2: Departing from the representation of the apparatus according to FIG. 1, the transport chamber and the arrangement of substrate treatment stations of a further embodiment of the apparatus according to the invention;

FIGS. 3A-3E: A sequence of operating steps (a) to (e) as an example of operating the apparatus according to the invention, thereby performing an example of the methods according to the invention;

FIGS. 4A-4G: Schematically and simplified different mechanical conceptions of the arrangement of a multitude of substrate carriers and of the arrangement of substrate treatment stations, according to further embodiments of the apparatus according to the invention.

FIG. 5: schematically an example of a further arrangement of treatment stations at an embodiment of the apparatus according to the invention.

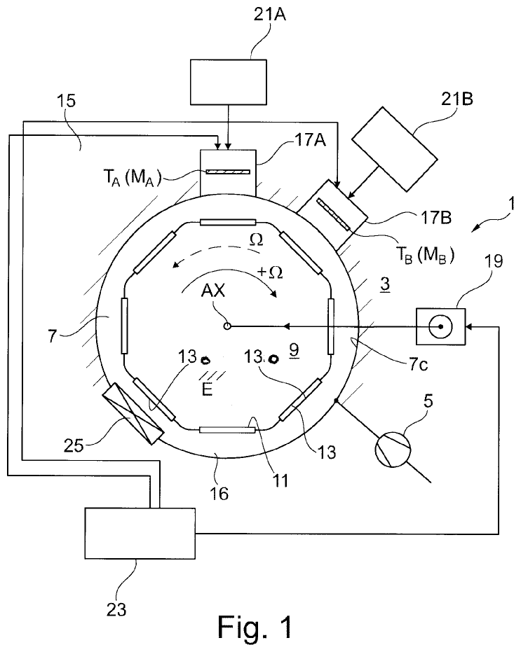

FIG. 1 shows, most schematically and simplified, an embodiment of the soft magnetic material multilayer deposition apparatus according to the invention. The apparatus 1 comprises a vacuum transport chamber 3 which is pumped by a pumping arrangement 5. The vacuum transport chamber 3 has a cylindrical inner space 7, cylindrical about an axis AX. Coaxially with the inner space 7 of the vacuum transport chamber 3 and in the inner space 7, there is provided a rotatably mounted cylindrical transport carrousel 9. Along a plane E, which accords with the drawing plane of FIG. 1 and which is perpendicular to the axis AX, an arrangement 16 of a multitude of substrate carriers 11 is provided, evenly distributed along the periphery of the transport carrousel 9. Each of the substrate carriers 11 is constructed to accommodate and hold a substrate 13 in a position so that one of the extended surfaces 13ₒ of each of the substrates 13 faces, in the embodiment of FIG. 1, the cylindrical surface 7_{c} of the cylindrical inner space 7.

Along the cylindrical surface 7_{c} of the inner space 7, still according to the embodiment of FIG. 1, there is provided an arrangement 15 of substrate treatment stations. In FIG. 1 two of these substrate treatment stations are shown and addressed with the reference signs 17A and 17B. The substrate treatment stations of the addresses arrangement 15 face towards the trajectory path of the substrate carriers 11 so that, being treatment-enabled, they treat the surfaces 13ₒ of the substrates 13.

A rotational drive 19 is operationally coupled to the transport carrousel 9 so as to rotate carrousel 9 about the axis AX. Thereby the arrangement 16 of the multitude of substrate carriers 11, loaded with the substrates 13, passes through the treatment areas of the respective treatment stations of the arrangement 15. Thus, there is established a relative rotation of the arrangement 16 of the multitude of substrate carriers 11 with respect to the arrangement 15 of treatment stations.

The arrangement 15 of treatment stations comprises or even, in a minimum configuration, consists of a first sputter deposition station 17A and of a second sputter deposition station 17B. The first sputter deposition station 17A has a first sputtering target T_{A} which consists of a first soft magnetic material to be deposited as a layer material on the substrates 13. This first target material is addressed in FIG. 1 by M_{A}. The material M_{A} may consist of one or more than one of the ferromagnetic elements Fe,Co,Ni or may comprise, beside of one or more than one of these elements, one or more than one of non-ferromagnetic elements. Such at least one non-ferromagnetic element may be one or more than one element out of the groups IIIA, IVB and VB of the periodic system (according to groups 13,4,5 of IUAPC), thereby especially out of the group B,Ta,Zr.

The second sputter deposition station 17B comprises a second target T_{B} which consists of a second soft magnetic material M_{B} which is to be deposited as a layer material on the substrates 13 and which is different from the soft magnetic material M_{A} of target T_{A} of the first sputtering station 17A. The material M_{B} may consist of one or more than one of the ferromagnetic elements Fe,Co,Ni or may comprise, beside of one or more than one of these elements, one or more than one of non-ferromagnetic elements. Such at least one non-ferromagnetic element may be one or more than one element out of the groups IIIA, IVB and VB of the periodic system (according to groups 13,4,5 of IUAPC), thereby especially out of the group B,Ta,Zr.

Thus, at these two sputtering stations 17A and 17B non-reactive sputter deposition is performed and the material to be deposited on the substrates 13 is the solid material of the respective target T_{A}, T_{B}. Thereby, and if M_{A} and/or M_{B} are materials of more than one element, the stoichiometry and constancy of the stoichiometry over time of the material deposited on the extended surfaces 13ₒ of the substrate 13 is accurately determined.

The sputtering stations 17A and 17B are electrically supplied by respective supply units 21A and 21B. Depending on the target material M_{A} and M_{B} the supply units 21A and 21B are DC-, pulsed DC-, including HIPIMS-supply units or are Rf supply units for single or for multiple frequency electric supply. It is also possible (not shown) to electrically bias the substrate carriers 11 of the arrangement 16 of the multitude of substrate carriers 11, either equally for depositing both materials M_{A} and M_{B} or selectively. In the embodiment of FIG. 1 this necessitates respective electric connections from biasing sources via the transport carrousel 9 to the substrate carriers 11.

The apparatus 1 further comprises a control unit 23. The control unit 23 on one hand controls the rotational drive 19 and thus relative rotational movement of the transport carrousel 9 and, on the other hand, treatment enablement and disablement of the sputter deposition stations 17A and 17B. Thereby, the control unit 23 maintains the sputter deposition stations 17A and 17B deposition-enabled, with respect to sputter depositing target material towards the substrate carriers 11 and thus upon the substrates 13 during more than one directly succeeding 360° relative revolutions of the arrangement 16 of the multitude of substrate carriers 11 with respect to the arrangement 15 of treatment stations, about axis AX. The number of revolutions during which the sputter deposition stations 17A and 17B are deposition-enabled, depends on the number of thin layers of the materials M_{A} and M_{B} to be deposited as a stack upon the extended surfaces 13ₒ of the substrates 13. The addressed more than one 360° relative revolutions during which the sputter deposition stations 17A and 17B are deposition-enabled, are directly succeeding one another.

E.g., to load and unload substrates 13 to the apparatus, according to the embodiment of FIG. 1 to the transport carrousel 9, as schematically shown in FIG. 1 e.g. via a two-directional load-lock arrangement 25, the control unit 23 does additionally control the arrangement 15 of treatment stations including the sputter deposition stations 17A and 17B to selectively disable respective treatment of the substrates 13. This may be realized either by disabling the respective electric supply units, as of 21A and 21B, or by closing and respectively opening a respective shutter (not shown) thereby interrupting substrate treatment by the respective station. This, especially with an eye on the fact that all substrates 13 treated by the apparatus 1 should be equally treated between being loaded to and being unloaded from the apparatus.

Whereas it is absolutely possible to perform the relative rotational movement of the arrangement 16 of the multitude of substrate carriers 11, according to FIG. 1 on the transport carousel 9 about axis AX, and addressed in FIG. 1 by the arrow Ω in incremental steps, in view of the object of depositing very thin layers especially of the materials M_{A} and M_{B}, in a good embodiment, the control unit controls the rotational drive 19 for a continuous relative rotation at a constant angular velocity with respect to axis AX at least during some of the addressed more than one 360° relative revolutions which directly succeed one another. By such continues constant speed relative rotation, according to FIG. 1 of the transport carrousel 9, further transitional states as may be caused by stop and go relative rotation are avoided. Avoiding any hardly controllable transitional states for sputter deposition of the very thin layers by the sputter deposition stations 17A and 17B improves controllability of such deposition. This is also valid for layer deposition on the substrates by possibly provided further layer deposition stations of the arrangement 15 of substrate treatment stations.

In the case, according to a good embodiment, in which the transport carrousel 9 is controlled via the rotational drive 19 and control unit 23 to relatively rotate at a constant angular relative speed about axis AX at least during some of the more than one 360° uninterrupted relative revolutions, the thickness of each very thin layer deposited especially by the sputter deposition stations 17A and 17B on the surfaces 13ₒ of the substrate 13 becomes governed by the power with which the respective sputtering stations 17A and 17B are supplied by the supply units 21A and 21B, in fact by the respective deposition rate i.e. amount of material deposited per time unit. Thus, the control unit 23 controls the power delivered by the supply units 21A and respectively 21B to the respective sputter deposition stations 17A and 17B, on one hand in dependency from the constant relative rotational speed of the arrangement 16 of the multitude of substrate carriers 11 with respect to the arrangement 15 of treatment stations and, on the other hand, in dependency from the desired very small layer thickness d₁ for material M_{A} and d₂ for material M_{B}.

If the arrangement 15 of treatment stations comprises further layer deposition stations which are deposition enabled during the same time as the first and second sputter deposition stations 17A,17B the same prevails: Deposition rate of such further stations is also controlled by the control unit 23 in dependency from the constant relative rotational speed as addressed and, on the other hand, in dependency from the desired very small layer thickness to be deposited by such further layer deposition station.

The thicknesses d including d₁,d₂ of the respective materials M_{A} and M_{B} and possibly of further materials, which are realized by the apparatus according to the invention and as exemplified in FIG. 1 were addressed above, controlled by control unit 23 for the constant relative rotational speed for multiple 360° revolutions and by respective control, by unit 23, of the supply units as of 21A and 21B of FIG. 1.

If the arrangement 16 of the multitude of substrate carriers 11, as on the transport carousel 9 of FIG. 1 is relatively rotated in incremental steps with respect to the arrangement 15 of treatment stations, the treatment stations of the arrangement 15 including the sputter deposition stations 17A and 17B must be angularly spaced equally to the mutual angular space of the substrate carriers 11, to make sure that at each relative incremental rotation the substrate carriers 11 become well aligned with one of the treatment stations.

If the addressed relative rotation is driven by rotational drive 19 and controlled by control unit 23 for constant relative angular speed rotation, then the angular spacing of treatment stations of the arrangement 15 needs not be adapted to the mutual angular spacing of the substrate carriers 11 e.g. along the transport carrousel 9.

Especially in that case, in which the relative rotation is controlled by the control unit 23 and via rotational drive 19 to be continuous for two or more than two 360° succeeding relative revolutions, homogeneity of the resulting overall stack of very thin layers is improved by inverting the direction of relative revolution e.g. of the transport carrousel 9, as shown in FIG. 1 in dashed lines at −Ω. Such inverting may be controlled by the control unit 23 after a desired number of thin layer having been deposited by the sputter deposition stations 17A and 17B.

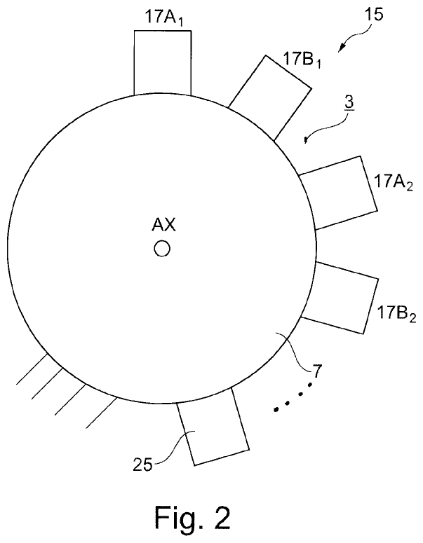

According to FIG. 2 which shows, still simplified and most schematically, the vacuum transport chamber 3, more than one couple of the sputter deposition stations 17A and 17B as of FIG. 1 are provided, represented by 17A₁, 17A₂, 17B₁, 17B₂ etc. whereby each sputter deposition station 17Aₓ having the respective target of the material M_{A} and, accordingly, each of the sputter deposition stations 17Bₓ having a target of the material M_{B} as was addressed also in context with FIG. 1. Nevertheless, more than one first and/or more than one second sputter deposition stations may have respective targets of different soft magnetic material E.g. a station 17_{A1} may have a target of soft magnetic material M_{A1}, a station 17_{A2} a target of a different soft magnetic material M_{A2} etc., and in analogy multiple second sputtering stations 17_{B1}, 17_{B2} etc.

As further shown in FIG. 2, in one embodiment of the apparatus, there is provided, as a part of arrangement 15 of treatment stations, a further layer deposition station 25. This deposition station may not be deposition-activated during the more than one 360° relative revolutions e.g. of the transport carrousel 9. By means of the control unit 23, not anymore shown in FIG. 2, the further layer deposition chamber 25 may only be deposition-activated, as by switching on the respective electrical supply and/or opening a shutter barring deposition upon substrates 13 (not shown in FIG. 2) at selected time spans, after completion of a predetermined number of the addressed continues 360° relative revolutions. By this deposition station 25, in a good embodiment, a thin layer of a dielectric material, as of aluminum oxide, silicon oxide, tantalum oxide, silicon nitride, aluminum nitride and the respective carbides or oxi-carbides or nitro-carbides etc. is deposited, e.g. as a final layer upon the yet finished stack of very thin layers of the materials M_{A} and M_{B} and/or as an intermediate dielectric layer after a first predetermined number of very thin layers of M_{A} and M_{B} having been deposited and before further depositing a further part of the stack of M_{A} and M_{B}.

Whereas in the embodiments of FIGS. 1 and 2 the sputter deposition stations 17A and 17B are neighboring each-others, in one embodiment there is provided a further treatment station in between the respective sputter deposition stations 17A and 17B, especially at least one further layer deposition station, especially at least one further sputter deposition chamber. By such further at least one layer deposition station at least one non-ferromagnetic element as one or more than one element out of the groups IIIA, IVB and VB of the periodic system (according to groups 13,4,5 of IUAPC), especially Boron and/or Tantalum and/or Zirconium may be deposited. If such at least one intermediate station is provided, then it might be operated continuously like the sputter deposition stations 17A and 17B or at selected intervals which means only after a predetermined number of very thin layers of the materials M_{A} and M_{B} having been deposited on the substrates 13.

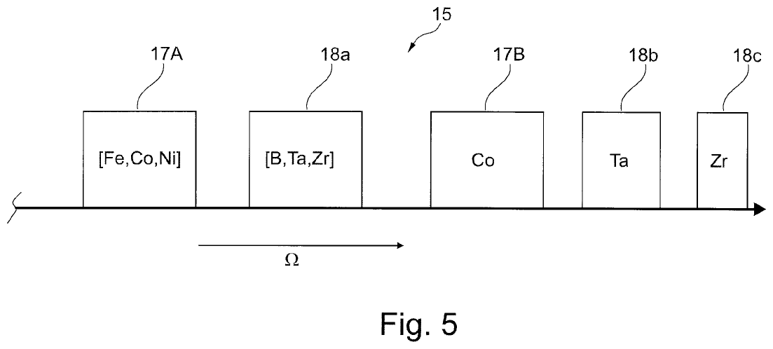

FIG. 5 shows most schematically along the trajectory path of relative rotation Ω of the arrangement 16 of the multitude of substrate carriers 11 (not shown in FIG. 5) with respect to the arrangement 15 of treatment stations an example of stations as arranged along the addressed trajectory path. The first sputter deposition station has a target consisting of at least one of the elements Fe,Ni,Co.

A neighboring succeeding further sputter deposition station 18a has a target of at least one of the element B,Ta,Zr.

The second sputter deposition station 17B has a target of Co. Neighboring succeed, further sputter deposition stations 18b and 18c are installed and have, respectively, targets of Ta and Zr.

All the stations 18a to 18c are, as an example, deposition enabled same time as the stations 17A and 17B.

To further improve magnetic characteristics of the very thin layers, collimators (not shown) may be provided between the respective targets T_{A} and T_{B} and the revolving substrate carriers 11. Such collimators may also be provided at further layer deposition stations of the arrangement 15 of treatment stations.

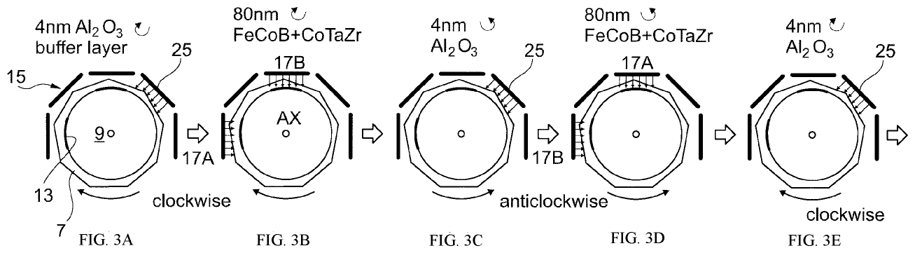

FIGS. 3A-3E show an example of operation of the apparatus e.g. according to the embodiments of FIG. 1 or 2. Therefrom, it might be seen that the cylindrical inner space 7 of the vacuum transport chamber 3 is to be understood also as cylindrically in the sense of approximated by a polygon.

In cycle according to FIG. 3A the layer deposition station 25 is deposition-enabled and all the substrates 13 on the transport carrousel 9 are coated with a buffer layer of aluminum oxide with a thickness of 4 nm. The transport carrousel 9 is clockwise continuously rotated at constant angular speed. Once the buffer layer of aluminum oxide has been deposited on the substrates 13, the deposition station 25, e.g. a Rf sputter deposition chamber operating on an aluminum oxide material target, is deposition-disabled. In the cycle of FIG. 3B the sputter deposition stations 17A and 17B are enabled for sputter deposition upon the buffer layer on the substrates 13, the transport carrousel 9 still revolving clockwise at constant angular speed. There are deposited, by 40 360° continuous revolutions, 40 couples of material M_{A} and M_{B} layers. The material M_{A} is Feₓ₆Co_{y6}B_{z6} and the material M_{B} is Coₓ₇Ta_{y7}Zr_{z7} with values of the stoichiometry factors x6,y6,z6 and x7,y7,z7 as were indicated above.

Specifically, and in one example, the material M_{A} was Fe₅₂Co₂₈B₂₀ and the material MB was Co_{91.5}Ta_{4.5}Zr₄. The sum of thicknesses d₁ and d₂ was about 2 nm.

There resulted a layer stack of the addressed M_{A}- and M_{B}-very thin layers with a total thickness of about 80 nm. After having deposited this layer stack of about 80 nm thickness, the deposition chamber 25, for aluminum oxide deposition, was deposition-enabled and a thin layer of about 4 nm thickness of aluminum oxide was deposited on the 80 nm layer stack according to cycle of FIG. 3C. Thereby the revolving direction of the transport carrousel 9 was inverted to anticlockwise. Subsequently and according to cycle of FIG. 3D, the deposition chamber 25 was again deposition-disabled and the sputter deposition stations 17A and 17B sputter deposition-enabled.

By subsequent 40 360° anticlockwise continuous revolutions of transport carrousel 9 there was again deposited a 80 nm stack of very thin layers of the material M_{A} and M_{B}.

Thereby it was found, that by reducing d₁ as well as d₂ of the layers deposited from the addressed M_{A} and M_{B} material targets, e.g. from 1 nm down to 0.2 nm, the magnetic property Hₖ of the stack was improved from 35 Oe to nearly 50 Oe maintaining coercivity extremely low, i.e. smaller than about 0.1 to 0.2 Oe, which is mandatory for soft magnetic multilayers as required by ultra-low loss RF passive devices.

According to cycle (e) and the possibly following further cycles, the cycles (a) to (c) may be repeated as often as desired.

It has to be noted that the stoichiometry parameters and xₙ,yₙ,zₙ may be varied within the ranges as were addressed above to further optimize the soft magnetic behavior of the resulting stack of very thin, soft magnetic material layers for very high frequency applications as of one or several GHZ.

The substrates which were coated in the example according to FIGS. 3A-3E were silicon substrates covered with a silicon oxide layer.

Whereas, according to the embodiments of FIG. 1 to 3, the substrate carriers 11 are arranged along the periphery of the transport carrousel 9 in a manner, that substrates supported therein have extended surfaces 13ₒ with normals which radially point outwards with respect to rotational axis AX and towards the respectively positioned stations of the arrangement 15.

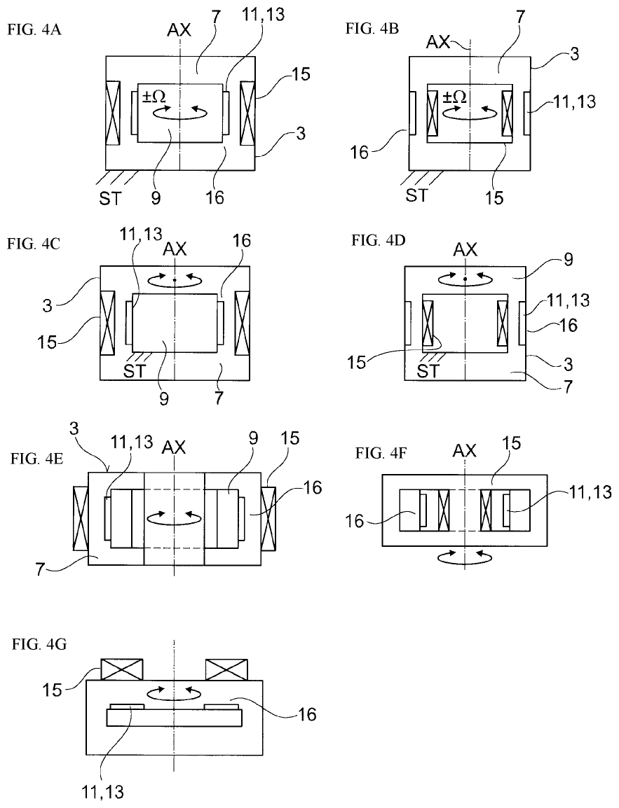

FIGS. 4(a) to (g) show most schematically various mechanical conceptions of the apparatus according to the invention in which a relative rotation of the arrangement 16 of the multitude of substrate carriers 11 with respect to the arrangement 16 of treatment stations is established.

In the embodiment of FIG. 4a the arrangement 15 of treatment stations is stationary. The arrangement 16 of the multitude of substrate carriers 11 with substrates 13 is rotatably and the surfaces to be treated of the substrates 13 face outwards with respect to axis AX, towards the stationary arrangement 15 of treatment stations.

In the embodiment of FIG. 4b the arrangement 16 of the multitude of substrate carriers 11 with the substrates 13 is stationary. The arrangement 15 of treatment stations is rotatable. The surfaces to be treated of the substrates 13 face inwardly with respect to axis AX, towards the rotatable arrangement 15 of treatment stations.

In the embodiment of FIG. 4c the arrangement 15 of treatment stations is rotatable. The arrangement 16 of the multitude of substrate carriers 11 with the substrates 13 is stationary and surfaces to be treated of the substrates 13 are directed outwards with respect to the axis AX and face the rotatable arrangement 15 of treatment stations.

In the embodiment of FIG. 4d the arrangement 16 of the multitude of substrate carriers 11 with substrates 13 is rotatable. The arrangement 15 of treatment stations is stationary. The surfaces of the substrates 13 to be treated are directed inwards with respect to axis AX and face the stationary arrangement 15 of treatment stations.

Please note that the stationary mount in the FIGS. 4a to 4d is schematically addressed by ST.

In the embodiment of FIG. 4e the inner space 7 of vacuum transport chamber 3 is not cylindrical as in the embodiments of FIG. 4a to 4d but is annular. The arrangement 15 of treatment stations is stationary or rotatable. The arrangement 16 of the multitude of substrate carriers 11 with the substrates 13 is, respectively, rotatable or stationary. The surfaces to be treated of the substrates 13 are directed outwards with respect to the axis AX a face the arrangement 15 of treatment stations.

In the embodiment of FIG. 4f the inner space 7 of the vacuum transport chamber 3 is not cylindrical as in the embodiments of FIG. 4a to 4d but is annular. The arrangement 15 of treatment stations is stationary or rotatable. The arrangement 16 of the multitude of substrate carriers 11 with the substrates 13 is respectively rotatable or stationary. The surfaces to be treated of the substrates 13 are directed inwards with respect to the axis AX and face the arrangement 15 of treatment stations.

In the embodiment of FIG. 4g the inner space 7 is cylindrical. The arrangement 15 of treatment stations is stationary or rotatable. The arrangement 16 of the multitude of substrate carriers 11 with the substrates 13 is, respectively, rotatable or stationary. The treatment directions of the stations of the arrangement 15 of treatment stations is parallel to the axis AX. The surface to be treated of the substrates 13 are directed parallel to the axis AX and face the arrangement 15 of treatment stations.

As now becomes apparent to the skilled artisan further mechanical combinations of realizing the arrangement 16 of the multitude of substrate carriers 11 for the substrates 13 and of the arrangement 15 of treatment stations are possible, without leaving the scope of the present invention.

All explanations which were given with respect to the embodiment of the FIGS. 1 to 3A-3E and 5 nevertheless prevail also for the embodiments according to FIGS. 4A-4G.

1. A method of manufacturing a substrate with a core for an induction device, comprising:
providing a vacuum transport chamber with a circular inner space about an axis;
providing along a plane perpendicular to said axis, a circular arrangement comprising a multitude of substrate carriers in said circular continuous inner space and coaxially to said axis;
providing along a plane perpendicular to said axis, a circular arrangement of substrate treatment stations being positioned to be treatment-operative into said circular continuous inner space;
providing a rotational drive operationally coupled between said circular arrangement of said multitude of substrate carriers and said circular arrangement of substrate treatment stations;
providing said circular arrangement of said multitude of substrate carriers and said circular arrangement of substrate treatment stations mutually aligned;
wherein at least one of said treatment stations is a first sputter deposition station with a single target;
wherein at least one of said treatment stations is a second sputter deposition station with a single target;
providing said single target of said first sputter deposition station of a first soft magnetic material;
providing said target of said second sputter deposition station of a second soft magnetic material different from said first soft magnetic material;
providing a control unit operationally coupled to said treating stations and to said rotational drive;
loading substrates to said substrate carriers;
establishing a relative rotation between said circular arrangement of said multitude of substrate carriers and said circular arrangement of said substrate treatment stations by said rotational drive;
depositing on said substrates a first layer of said first soft magnetic material and a second layer of said second soft magnetic material;
controlling by said control unit said at least one first sputter deposition station and said at least one second sputter deposition station to continuously sputter-deposit towards and onto said circular arrangement comprising said multitude of said substrate carriers, at least during more than one 360° revolution of said circular arrangement comprising said multitude of said substrate carriers relative to said circular arrangement of said substrate treatment stations and about said axis, said more than one 360° revolutions directly succeeding one another; and
depositing during at least some of said more than one revolution, layers of said first soft magnetic material and layers of said second soft magnetic material directly one upon the other on said substrates.

2. The method of claim 1,
wherein said circular continuous inner space comprises an annular or cylindrical continuous inner space, and wherein said arrangement of said multitude of said substrate carriers or said circular arrangement of said substrate treatment stations is mounted to the radially outer circular surface of said continuous annular inner space or to the surrounding surface of said continuous cylindrical inner space or to the top or bottom surface of said continuous annular inner space or of said continuous cylindrical inner space or to the radially inner circular surface of said continuous annular inner space.

3. The method of claim 1, wherein said first soft magnetic material comprises or consists of one or more than one element out of the group Fe, Ni, Co and said second soft magnetic material comprises or consists of one or more than one element of the group Fe, Ni, Co.

4. The method of claim 1, wherein at least one of said first soft magnetic material and said second soft magnetic material comprises one or more than one element out of the group Fe, Ni, Co and at least one non-ferromagnetic element.

5. The method of claim 4, wherein said at least one non-ferromagnetic element comprises at least one element out of the groups IIIA, IVB and VB of the periodic system (according to groups 13,4,5 of IUAPC) or at least one of the group B,Ta,Zr.

6. The method of claim 1, comprising establishing said relative rotation between said circular arrangement of said multitude of substrate carriers and said circular arrangement of said substrate treatment stations by said rotational drive to be continuous for at least some of said more than one 360° revolutions directly succeeding one another.

7. The method of claim 1, comprising controlling by said control unit sputtering powers of at least said first and of said second sputter deposition stations and exposure time each of said substrates is exposed to said first and to said second sputter deposition stations, respectively, and depositing by each of said first and second sputter deposition stations a layer of said first and of said second soft magnetic materials, respectively, of a respectively desired thickness d₁,d₂, being
0.5 nm≥(d₁,d₂,)≥0.1 nm or
0.5 nm≥(d₁,d₂,)≥0.2 nm.

8. The method of claim 7, comprising depositing said first layer of FeCoB and said second layer of CoTaZr.

9. The method of claim 1, comprising at least one further layer deposition station, wherein said control unit controls the material deposition rate of said further layer deposition station in dependency of an exposure time each of said substrate carriers is exposed to said further layer deposition station, so as to deposit by said further layer deposition station a layer of a desired thickness d₃ for which there is valid:
10 nm≥(d₃)≥0.1 nm.

10. The method of claim 1, wherein said first and said second sputter deposition stations are two layer deposition stations of a group of more than two layer deposition stations, positioned along said continuous inner space one neighboring the other.

11. The method of claim 10, comprising providing more than one of said groups and/or different of said groups.

12. The method of claim 1, wherein said arrangement of substrate treatment stations comprises at least one further sputter deposition station for sputter depositing a further material towards said substrate carriers.

13. The method of claim 12, wherein said further material comprises a non-magnetic metal or metal alloy or a dielectric material.

14. The method of claim 1, comprising selecting one of said first and of said second targets of Feₓ₁Co_{y1}, wherein there is valid x1+y1=100 and 20<y1<50 and providing a further sputter deposition station neighboring succeeding said one sputter deposition station and depositing by said further sputter deposition station Boron, and enabling said further sputter deposition station directly after enabling said one sputter deposition station.

15. The method of claim 1, comprising selecting at one of said first and of said second sputter deposition station respectively one of said first and of said second targets of Co, providing at said arrangement of treatment stations at least two further sputter deposition stations, neighboring said selected one sputter deposition station and having targets of Ta and of Zr.

16. The method of claim 1, wherein at least one of said first and of said second targets comprises Feₓ₂Co_{y2}B_{z2}, wherein x2+y2+z2=100.

17. The method of claim 1, wherein at least one of said first and second targets comprises Niₓ₃Fe_{y3}, wherein x3+y3=100 and there is valid 50<y3<60 or 17.5<y3<22.5.

18. The method of claim 1, wherein said first target comprises Feₓ₄Co_{y4}, said second target comprises Niₓ₅Fe_{y5} whereby there is valid x4+y4=100 and x5+y5=100 and 5<y4<20 and 17.5<y5<22.5 or 50<y5<60.

19. The method of claim 1, wherein said first target comprises Feₓ₆Co_{y6}B_{z6} and said second target comprises Coₓ₇Ta_{y7}Zr_{z7}, wherein x6+y6+z6=100 and x7+y7+z7=100 and wherein there is valid at least one of:
x6>y6,
y6≥z6,
x7>y7,
y7≥z7.

20. The method of claim 1, wherein said first target comprises Feₓ₆Co_{y6}B_{z6} and said second target comprises Coₓ₇Ta_{y7}Zr_{z7}, wherein x6+y6+z6=100 and x7+y7+z7=100 wherein there is valid at least one of:
45≤x6≤60,
50≤x6≤55,
x6=52,
20≤y6≤40,
25≤y6≤30,
y6=28,
10≤z6≤30,
15≤z6≤25,
z6=20,
85≤x7≤95,
90≤x7≤93,
x7=91.5,
3≤y7≤6,
4≤y7≤5,
y7=4.5,
2≤z7≤6,
3≤z7≤5,
z7=4.
